(19) United States
(12) Patent Application Publication
(10) Pub. No.: US 2012/0025185 A1
(43) Pub. Date: Feb. 2, 2012

(54) ELECTROLUMINESCENCE DEVICE

(75) Inventor: Tadashi Kasamatsu, Ashigarakami-gun (JP)

(73) Assignee: FUJIFILM CORPORATION, Minato-ku, Tokyo (JP)

(21) Appl. No.: 13/262,445

(22) PCT Filed: Mar. 29, 2010
(86) PCT No.: PCT/JP2010/002287

§ 371 Date: Sep. 30, 2011

(30) Foreign Application Priority Data
Mar. 30, 2009 (JP) 2009-082790

(51) Int. Cl. H01L 51/52

(52) U.S. Cl. 257/40; 257/E51.018

(57) ABSTRACT

An electroluminescence device (1) realizes high light emission efficiency, high durability, and high extraction efficiency. The device includes electrodes (11, 17); a plurality of layers (12 through 16) that are deposited between the electrodes (11, 17); and a light emitting region (14) between the plurality of layers (12 through 16). The light emitting region (14) emits light by application of an electric field between the electrodes (11, 17). The thickness and the refractive index of each of the plurality of layers (12 through 16) satisfy a resonance condition in the electroluminescence device (1) that makes a region in which the intensity of the electric field of a standing wave (19) by the light emitted from the light emitting region (14) is the highest substantially coincide with the light emitting region (14). A metal member (20) that induces plasmon resonance on the surface thereof by the emitted light is arranged in the vicinity of the light emitting region (14).

### TECHNICAL FIELD

The present invention relates to an electroluminescent light emitting device (electroluminescence device), which emits light by application of an electric field, and particularly to an electroluminescence device that can emit light with high efficiency.

### BACKGROUND ART

Electroluminescence devices (EL devices), such as an organic EL device, an LED (light emitting diode), and a semiconductor laser, are structured in such a manner that electrode layers, a light emitting layer and the like are deposited (stacked, superposed or the like) one on another on a substrate. Generally, light generated in the light emitting layer is extracted through a transparent electrode. However, when light enters the interface of the light-extracting-side layer at an angle greater than or equal to a critical angle by influence of the refractive index of each layer, total reflection occurs. Therefore, the light is trapped in the electroluminescence device, and it is impossible to extract the light therefrom. Hence, highly efficient extraction of emitted light is difficult. For example, when the refractive index of the transparent electrode is the refractive index of ITO (indium-tin oxide) or the like, which is often used as the material of the transparent electrode, the light extraction efficiency is said to be approximately 20%.

For example, in an organic EL device, it is known that when an organic material is present in an excited state for a long period of time, the chemical bond of the organic material breaks inherently, and that the light emitting performance of the organic EL device deteriorates as time passes. It is essential to solve this problem when the organic material is used as the material of the electroluminescence device (light emitting device). Further, as long as fluorescence is used, generation efficiency at an upper level (an upper energy level or state) is theoretically limited to 25%, and it is impossible to increase the light emitting efficiency more than this level. In principle, when phosphorescence is used and intersystem crossing is promoted, it is possible to induce the upper level including only triplets. Therefore, the theoretical limit may be increased to a range of 75% to 100%. However, the lifetime of the triplet in the upper level is longer than that of fluorescence, which is emitted in allowed transition, and the probability of collision between excitons is high. Therefore, the light emitting efficiency is lower. Further, the device deteriorates faster, and the durability of the device is low.

As described above, the extraction efficiency and the light emitting efficiency of the EL device are low. Therefore, the utilization efficiency of the emitted light is extremely low, and the utilization efficiency needs to be improved.

To solve such problems, various approaches were used to improve the extraction efficiency and the light emitting efficiency (or to enhance light emission).

For example, Japanese Unexamined Patent Publication No. 2006-313667 proposes an organic EL device in which the directivity of light emission is controlled to improve the utilization efficiency of the extracted light. The organic EL device includes an uneven pattern having projections and depressions on the surface of an electrode. Further, the light emitting layer of the organic EL device is made of a light emitting material that has a narrow light emission spectral width.

Further, J. Chang and A. W. Lu, “Cavity design and optimization for organic microcavity OLEDs”, Proc. SPIE, Vol. 6038, 603824, 2005, W. L. Barnes, “Fluorescence near interfaces: the role of photonic mode density”, Journal of Modern Optics, Vol. 45, pp 661-699, 1998, and W. Li et al., “Emissive Efficiency Enhancement of Alg₃ and Prospects for Plasmon-enhanced Organic Electroluminescence”, Proc. SPIE, Vol. 7032, pp. 703224-1-703224-7, 2008 propose, as methods for improving the light emission efficiency (enhancing light emission), a method using a microcavity effect and methods using plasmon enhancement effects.

In the method using the microcavity effect, a resonator is provided in the organic EL device to control the directivity of light emission (to narrow). Further, the loop (anti-node) of a standing wave (a position at which the intensity of the electric field by the standing wave is highest) is matched with the light emitting portion to enhance light emission. J. Chang and A. W. Lu, “Cavity design and optimization for organic microcavity OLEDs”, Proc. SPIE, Vol. 6038, 603824, 2005 proposes a method that adopts a structure including mirrors on either end of an organic EL device. In the method, a silver mirror and a copper mirror are arranged on either end of the organic EL device so that the microcavity effect is positively exhibited.

Meanwhile, in the method using the plasmon enhancement effect, metal (island-form pattern or structure is desirable) is arranged in the vicinity of the organic light emitting device (for example, within a few dozens of nanometers (nm)) to enhance light emission (please refer to W. L. Barnes, “Fluorescence near interfaces: the role of photonic mode density”, Journal of Modern Optics, Vol. 45, pp. 661-699, 1998, and W. Li et al., “Emissive Efficiency Enhancement of Alg₃ and Prospects for Plasmon-enhanced Organic Electroluminescence”, Proc. SPIE, Vol. 7032, pp. 703224-1-703224-7, 2008. The light emission is enhanced by inducing plasmons (or localized plasmons) on the surface of metal by dipoles output (radiated) from the light emitting device. After energy is absorbed, new light emission by re-radiation of the energy is added to the light emission. Therefore, the light emission transition by plasmons is added to the light emission process of the light emitting device. Hence, it is possible to reduce the lifetime in the upper level (excitation lifetime). As described above, the method using the plasmon enhancement effect can improve the light emission efficiency. Further, an improvement in the durability of the device can be expected by reduction of the excitation lifetime.

As described above, the microcavity has been applied to the organic EL device. However, the enhancement of light emission by the microcavity effect is insufficient for practical use. Further, the enhancement of light emission by the plasmon enhancement effect, as disclosed in Barnes W. L., “Fluorescence near interfaces: the role of photonic mode density”, Journal of Modern Optics, Vol. 45, pp 661-699, 1998, has been reported in a photo-excitation-type light emitting device (photoluminescence device: PL device). However, no successful case has been reported for the EL device.

### DISCLOSURE OF INVENTION

In view of the foregoing circumstances, it is an object of the present invention to provide an EL device that can realize high light emission efficiency, high durability and high light extraction efficiency.

An electroluminescence device of the present invention is an electroluminescence device comprising: electrodes;

a plurality of layers that are deposited one on another between the electrodes; and
a light emitting region between the plurality of layers, the light emitting region emitting light by application of an electric field between the electrodes, wherein the thickness and the refractive index of each of the plurality of layers satisfy a resonance condition in the electroluminescence device that makes a region in which the intensity of the electric field of a standing wave by the light emitted from the light emitting region is the highest substantially coincide with the light emitting region, and wherein a metal member that induces plasmon resonance on the surface thereof by the emitted light is arranged in the vicinity of the light emitting region.

Specifically, the electroluminescence device of the present invention has a structure in which a microcavity effect and a plasmon enhancement effect are utilized in combination.

Here, the term “electroluminescence device” is a general term representing a device that outputs light by application of an electric field. Therefore, the electroluminescence device may be an organic EL device, an inorganic EL device, a light emitting diode (LED), a semiconductor laser (LD), or the like.

When the electroluminescence device is an organic EL device, it is desirable that the plurality of layers include at least an electron transport layer, a light emitting layer, and a positive-hole transport layer, and each of which is formed of an organic layer. When the electroluminescence device in an LED or LD, it is desirable that the plurality of layers include at least a p-type clad layer, an active layer, and an n-type clad layer, and each of which is formed of a semiconductor layer.

It is desirable that a distance between the metal member and the light emitting region is less than or equal to 30 nm.

It is desirable that the metal member is a metal thin-film arranged between the plurality of layers. The metal thin-film may be a metal thin-film that spreads without interruption or a gap) (hereinafter, also referred to as a solid metal thin-film). Alternatively, the metal thin-film may be a particle-pattern thin-film (a thin-film that has an even pattern of projections and depressions less than the wavelength of the emitted light). It is desirable that the metal microparticles having particle diameters of greater than or equal to 5 nm are dispersed, in layer form, randomly or in periodic arrangement pattern. Here, the term “particle diameter” refers to the longest length or diameter of a microparticle. Specifically, when the microparticle is a sphere, the diameter of the sphere is the particle diameter of the microparticle. When the microparticle is in rod form, the major axis of the rod is the particle diameter of the microparticle.

As the material of the metal thin-film, a material that induces plasmon resonance by emitted light should be used. For example, Ag (silver), Au (gold), Cu (copper), Al (aluminum), Pt (platinum) or an alloy containing one of these metals as a main component may be used. Here, the term “main component” is defined as a component the content of which is greater than or equal to 80 weight percent (wt %).

Among these materials, Ag and Au are desirable.

Further, it is desirable that surface modification is provided on at least one of the surfaces of the metal thin-film, the surface modification including an end group having polarity that makes the work function of the metal thin-film become close to the work function of at least a layer next to the metal thin-film. When the work function of the metal thin-film is less than the work function of each of layers next to the metal thin-film on either side of the metal thin-film (cathode side), the end group is an electron donor group. When the work function of the metal thin-film is greater than the work function of each of layers next to the metal thin-film on either side of the metal thin-film (anode side), the end group is an electron withdrawing group.

The end group having polarity refers to an electron donor group, which donates electrons, and an electron withdrawing group, which withdraws electrons. Examples of the electron donor group are an alkyl group, such as a methyl group, an amino group, a hydroxyl group, and the like. Examples of the electron withdrawing groups are a nitro group, a carboxyl group, a sulfo group, and the like.

The metal member may be a core-shell-type microparticle including at least one metal microparticle core and an insulation shell that covers the at least one metal microparticle core. It is desirable that a multiplicity of core-shell-type microparticles are dispersed in a layer in the vicinity of the light emitting region. The core-shell-type microparticles may be present in the light emitting region. It is desirable that the particle diameter of the metal microparticle core of the core-shell-type microparticle is greater than or equal to 10 nm and less than or equal to 1 um (micro meter). Further, it is desirable that the thickness of the insulation shell is less than approximately 30 nm. Here, the term “particle diameter” refers to the longest diameter (length) of a microparticle.

When the core-shell-type microparticle or the metal microparticle is an elongated microparticle (an oval microparticle), in which the aspect ratio of the major axis of the microparticle to the minor axis of the microparticle, which is perpendicular to the major axis, is greater than 1, it is desirable that a multiplicity of elongated microparticles are arranged in such a manner that the minor axes of the microparticles are oriented in a direction substantially perpendicular to the surfaces of the electrodes.

Further, a plurality of metal microparticle cores may be provided in the insulation shell.

It is desirable that the metal microparticle core is made of Au, Ag, Al, Cu and Pt or an alloy containing one of these metals as a main component.

As the material of the insulation shell, an insulator, such as SiO₂, Al₂O₃, MgO, ZrO₂, PbO, B₂O₃, CaO, and BaO, may be uses.

In the electroluminescence device of the present invention, a cavity is formed in the device. Further, a light emitting region is arranged in the vicinity of the loop of a standing wave (a position at which the intensity of the electric field is highest) of the emitted light, which is formed in the cavity. Further, the metal member is arranged in the vicinity of the loop of the standing wave. Therefore, it is possible to enhance the spontaneous emission in the light emitting region. Further, since a resonator is provided in the device, it is possible to improve the directivity of light emission. In the electroluminescence device of the present invention, it is possible to enhance the light emission by making the loop of the standing wave coincide with the light emitting region. Further, the enhancement of light emission reduces the excitation lifetime. Further, since the metal member is arranged as described above, it is possible to enhance light emission by light emission transition by plasmons and to reduce the lifetime (excitation lifetime) in the upper level. Therefore, a synergic effect of the microcavity effect and the plasmon enhancement effect can be achieved. Accordingly, it is possible to improve the directivity of light emission, the efficiency of light emission, and the durability by reduction of the excitation lifetime. Further, it is possible to improve the extraction efficiency.

### BRIEF DESCRIPTION OF DRAWINGS

FIG. 1 is a schematic diagram illustrating the structure of an EL device according to a first embodiment of the present invention;

FIG. 2 is a schematic diagram illustrating the structure of an EL device according to a second embodiment of the present invention;

FIG. 3 is a diagram for explaining a work function adjustment layer of the EL device illustrated in FIG. 2; and

FIG. 4 is a schematic diagram illustrating the structure of an EL device according a third embodiment of the present invention.

### BEST MODE FOR CARRYING OUT THE INVENTION

Embodiments of the present invention will be described with reference to drawings.

### <El Device According to First Embodiment>

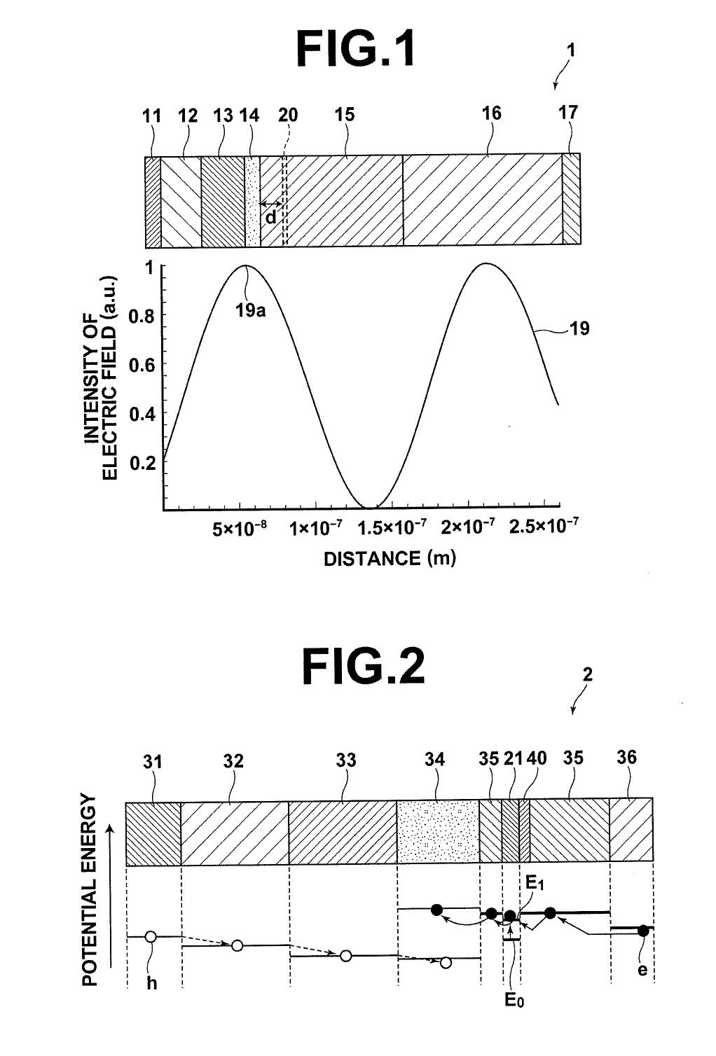

FIG. 1 is a schematic diagram illustrating the structure of an electroluminescence device (EL device) 1 according to the present embodiment. The EL device of the present embodiment is an organic EL device including layers, and each of which is formed of an organic layer.

The organic EL device 1 of the present invention has ordinary EL device structure basically including a cathode 11, an electron injection layer 12, an electron transport layer 13, a light emitting layer 14, a positive-hole transport layer 15, a positive-hole injection layer 16, and an anode 17. The light emitting layer 14 is Alq3 in this example. When electrons and positive-holes (holes), which are injected from the cathode 11 and the anode 17 respectively, are combined with each other in this region (light emitting region or layer), light is emitted. Further, the cathode 11 and the anode 17 are made of metal, and correspond to reflection portions that reflect emitted light. Further, the cathode 11 and the anode 17 have a function of forming an optical resonator therebetween. Here, the cathode 11 is made of Ag (silver), and the anode 17 is made of Cu (copper). When a standing wave 19 is generated between the electrodes 11, 17 (the cathode 11 and the anode 17), it is possible to improve the directivity of the emitted light. Further, when the loop 19a of the standing wave 19 coincides with the light emitting layer, it is possible to maximize the intensity of the electric field in the light emitting layer 14. Therefore, it is possible to maximize the light emitting efficiency. The resonance condition for achieving the microcavity effect as described above is given by the following formula. Each of the layers 12 through 16 is designed to have a refractive index and a thickness that satisfy the formula. In the following formula, λ₀ is the wavelength of emitted light, nᵢ is the reflective index of each layer, dᵢ is the thickness of each layer, p₁ and p₂ are phase differences by reflection at the cathode 11 and the anode 17 respectively, and m is the degree (order) of cavity:

$$\frac{4 π}{{λ}_{0}} {\sum }_{i} {n}_{i} {d}_{i} - {p}_{1} - {p}_{2} = 2 m π . \qquad [ Formula 1 ]$$

Further, in the organic EL device 1, a metal thin-film 20, as a metal member that induces plasmon resonance by the emitted light, is arranged in the vicinity of the light emitting region (light emitting layer 14). As long as the thickness of the metal thin-film 20 is less than or equal to approximately 10 nm, the above formula I is substantially not affected by the thickness of the metal thin-film 20. However, it is desirable that the thickness of the metal thin-film 20 is thin so that the metal thin-film 20 does not act as a reflective material. When the metal thin-film 20 is in contact with the light emitting layer 14 or located in the vicinity of the light emitting layer 14 by distance d of less than 5 nm from the light emitting layer 14, charges move directly from the light emitting layer 14, and the light emission attenuates. Therefore, it is desirable that the distance between the metal thin-film 20 and the light emitting layer 14 is at least 5 nm. However, if the metal thin-film 20 is too far from the light emitting layer 14, plasmon resonance by the emitted light does not occur, and the light emission enhancement effect is not achieved. Therefore, it is desirable that the distance between the metal thin-film 20 and the light emitting layer 14 is less than or equal to 30 nm.

The metal thin-film 20 may be a flat thin-film or a layer. However, it is desirable that the metal thin-film 20 has an even pattern (structure) including projections and depressions that are less than the wavelength of the emitted light. Specifically, it is desirable that the metal thin-film 20 is a particle-form thin-film, the surface of which has a particle pattern, or an island (island form) pattern thin-film. In the island pattern thin-film, metal microparticles that have particle diameters of greater than or equal to 5 nm are dispersed, in layer form, randomly or in a periodic arrangement pattern. In the island pattern, gaps are present between the metal microparticles. When the metal thin-film 20 is a flat thin-film, surface plasmons are induced on the surface of the metal thin-film by the emitted light. However, recombination for radiation mode does not tend to occur, and the ratio of finally disappearing as heat through non-radiation process is high. In contrast, when the metal thin-film 20 has the island pattern, the surface plasmons induced on the surface of the metal thin-film 20 by the emitted light are recombined for radiation mode, and the efficiency of outputting radiation light is high.

As the material of the metal thin-film 20, a material that induces plasmon resonance by emitted light should be used. For example, Ag (silver), Au (gold), Cu (copper), Al (aluminum) or an alloy containing one of these metals as a main component (greater than or equal to 80%) may be used. When the emitted light has a wavelength in the visible light range, silver is desirable based on the plasma frequency thereof, because silver can induce surface plasmon re because of the plasma frequency. When the wavelength of the emitted light is not in the visible light range, for example, if the wavelength of the emitted light is in an infrared ray range, it is desirable that the material is gold.

In the microcavity-type organic EL device as illustrated in FIG. 1, the light emitting layer 14 is arranged at a position within 10% from the loop (peak) of the standing wave, at which the intensity of the electric field is the highest. Further, the metal thin-film (here, an island pattern thin-film made of Ag) 20 is arranged at a position apart from the light emitting layer 14 by approximately 20 nm. When the metal thin-film 20 is arranged in the vicinity of the loop of the standing wave, in other words, when the metal thin-film 20 is arranged at a position in which the intensity of the electric field by the standing wave is high, it is possible to achieve the plasmon enhancement effect more efficiently, and that is desirable. When the organic EL device is structured as described above, the microcavity effect can enhance the light emission, control the directivity, and improve the durability. Further, the plasmon enhancement effect can enhance the light emission, control the directivity, and improve the durability. Therefore, the combination of the two effects achieves a greater effect than an effect achieved by each of the effects alone. This structure design adopts the degree m of cavity of 1 (m=1).

When the combination of the microcavity effect and the plasmon enhancement effect is compared with the microcavity effect or the plasmon enhancement effect alone, the light emission efficiency has been improved by 2 to 5% (depending on the operation conditions). Further, the durability has been improved to approximately 1.2-fold. Consequently, the utilization efficiency of the emitted light is remarkably improved, compared with a conventional device.

In the above embodiment, the electrodes 11, 17 are made of metal, and a cavity is formed between the electrodes 11, 17 to form a standing wave within the EL device 1. The reflectance of the electrodes for the emitted light should be sufficient to form the standing wave. In the present embodiment, the thickness of the electrode on the light extracting side (the anode 17 made of Cu in this example) is adjusted so that the reflectance is, for example, approximately 30%. Meanwhile, the reflectance of the silver-side electrode may be greater than or equal to 90%. Further, when a transparent electrode is provided as the electrode, a reflective layer may be provided on the outside of the electrode. The reflective layer may be made of metal that has an appropriate reflectance, or a dielectric multilayer.

In the above embodiment, a case in which the EL device is an organic EL device including organic layers was described. The structure of the present invention may be applied to various kinds of devices other than the organic EL device. For example, the present invention may be applied to an inorganic electroluminescence device, an LED (light emitting diode), an LD (laser diode), and the like.

In the EL device as described above, layers are sequentially deposited on the substrate from the cathode side, and light is extracted from the anode side, for example. Layers other than the metal thin-film may be formed by using materials and deposition or application methods that are used in conventional organic EL devices. Further, the metal thin-film (island pattern thin-film) may be formed, for example, by sputtering, vapor deposition, or the like.

### <EL Device According to Second Embodiment>

FIG. 2 is a schematic diagram illustrating the structure of an electroluminescence device 2 according to the second embodiment. In FIG. 2, the potential energy of each layer is also illustrated. As illustrated from the left side of FIG. 2, the EL device 2 of the present embodiment includes an anode 31, a positive hole injection layer 32, a positive hole transport layer 33, a light emitting layer 34, an electron transport layer 35, and a cathode 36. Further, a metal thin-film 21 is arranged in the electron transport layer 35. Further, a work function adjustment layer 40 is provided on a surface of the metal thin-film 21. The work function adjustment layer 40 is a surface modification layer that includes an end group having a polarity that makes the work function of the metal thin-film 21 become closer to the work function of a layer next to the metal thin-film 21 (the electron transport layer 35 in this case).

The EL device 2 of the present embodiment is also structured in such a manner that a cavity is formed between the electrodes 31 and 36 and a standing wave is generated in the device. In the EL device 2, the loop of the standing wave substantially coincides with the light emitting layer 34. Each of the layers 32 to 35 is designed to have a refractive index and a thickness that satisfy the above mentioned resonance conditions. Further, the metal thin-film 21 is arranged in a region in which plasmon resonance occurs by the light emitted from the light emitting layer 34. Accordingly, in a manner similar to the EL device of the first embodiment, it is possible to achieve the combined effect of the microcavity effect and the plasmon enhancement effect.

In FIG. 2, black circles represent electrons e, and white circles represent holes (positive holes) h. As illustrated in FIG. 2, generally, each layer of an EL device is arranged in such a manner that the work function of each layer continuously changes from the anode 31 side or the cathode side 36 toward the light emitting layer 34. The work function of the metal thin-film 21 inserted in the electron transport layer 35 is greater than the work function of the electron transport layer 35 (the potential energy of the metal thin-film 21 is lower). Therefore, when an electric field is applied, an electron trap may occur, and the flow of electrons may be prevented. If the flow of electrons is prevented, recombination in the light emitting layer 34 does not occur. Hence, there is a risk that light is not emitted sufficiently.

The work function adjustment layer 40 has a function of suppressing electron trap by the metal thin-film 21. The work function adjustment layer 40 lowers the effective work function of the metal thin-film 21 (increases the potential energy). In other words, in FIG. 2, the work function adjustment layer 30 changes ordinary energy level E₀ of the metal thin-film 21 to effective energy level E₁, thereby preventing the metal thin-film 21 from trapping electrons e. Consequently, the electrons e are moved to the light emitting layer side.

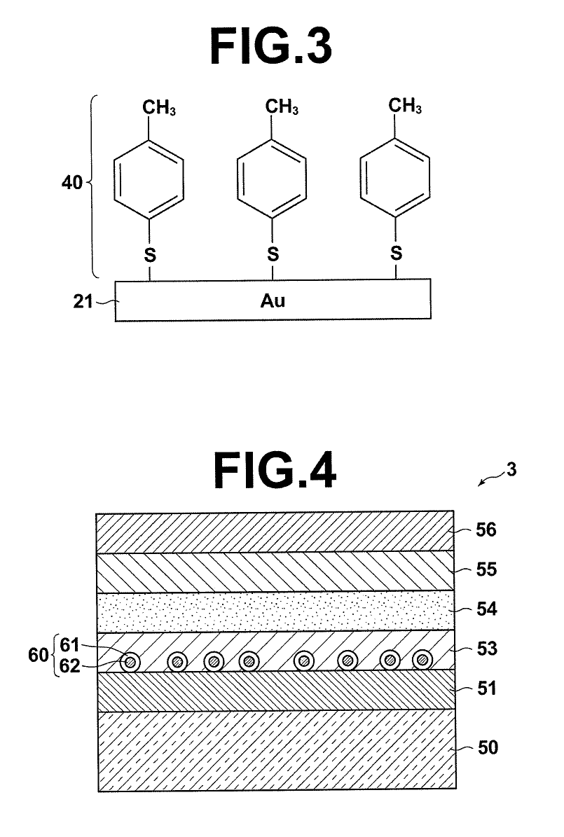

FIG. 3 is a diagram illustrating an example of the work function adjustment layer 40. In this example, the metal thin-film 21 is made of Au. As illustrated in FIG. 3 the work function adjustment layer 40 is a SAM (self-assembled monolayer) formed on the surface of the thin-film 21 of Au. The SAM binds to the surface of the thin-film 21 of Au by reaction of thiol or disulfide, which has an end group having a polarity, with Au. In the example illustrated in FIG. 3, the SAM is made of benzenethiol (thiophenol), which has a methyl group at a para position of a thiol group.

An alkyl group, such as the methyl group, is an electron donor group. When such an end group is included, the electron donor characteristics of the electron donor group increase the potential energy of Au, and lower the work function of Au. Examples of the electron donor group are an alkyl group, such as a methyl group, an amino group, a hydroxyl group, and the like.

After an Au thin-film 21 is formed, the work function adjustment layer 40 may be formed on the Au thin-film 21 by using a general method for producing SAM. It is desirable to use a liquid phase method, such as an application method (coating method), a vapor deposition method, or a sputter method. The work function adjustment layer 40 may be provided on one side of the metal thin-film 21 or on either side of the metal thin-film 21.

Here, a case of inserting the metal thin-film 21 into the electron transport layer 35 has been described. Alternatively, the metal thin-film 21 may be inserted into the positive hole transport layer 33 on the anode side. In that case, the work function of the metal thin-film 21 is lower than the work function of the positive hole transport layer 33 (potential energy is higher). Therefore, it is sufficient if the work function adjustment layer 40 for lowering the potential energy of the metal thin-film 21 is provided only on one side of the metal thin-film 21 so that the work function of the metal thin-film 21 becomes close to the work function of the positive hole transport layer 33. In this case, if the work function adjustment layer 40 includes, as an end group, an electron withdrawing group instead of the electron donor group illustrated in FIG. 3, the work function adjustment layer 40 lowers the effective potential energy of the metal thin-film 21, and the work function of the metal thin-film 21 becomes close to the work function of the positive hole transport layer 33. Examples of the electron withdrawing group are a nitro group, a carboxyl group, a sulfo group, and the like.

As described above, the work function adjustment layer (a polar molecular layer) 40 for adjusting the work function of the metal thin-film 21 is provided. Therefore, it is possible to prevent an adverse effect caused by the metal thin-film with respect to the movement of charges during application of an electric field. Hence, it is possible to effectively improve the light emission efficiency and the durability by the microcavity effect and the plasmon enhancement effect.

An organic LED having surface modification on metal by using SAM (self-assembled monolayer) including an electron donor group is described in “Tuning the Work Function of Gold with Self-Assembled Monolayers Derived from X—[C₆H₄—C≡C—]nC₆H₄—SH (n=0, 1, 2; X═H, F, CH₃, CF₃, and OCH₃)”, Robert W. Zehner et al., Langmuir, 1999, 15, p. 1121-1127. In the organic LED, the surface modification adjusts the work function of a metal electrode with respect to an organic polymer that forms Schottky barrier with the metal electrode. Further, Toru Toda, et al., “Enhancement of Positive Hole Injection to Liquid-Crystalline Semiconductor from Au Electrode Surface-Modified by Thiols”, Journal of the Society of Photographic Science and Technology of Japan, 70, No. 1, pp. 38-43, 2007 describes controlling the flow of electrons by providing surface modification on metal by using an electron donor group or an electron withdrawing group to adjust the energy level of gold or silver.

Therefore, if only the energy level of the metal thin-film should be adjusted, the technique disclosed in the above documents may be applied to the metal thin-film. However, if the technique is simply applied, there is a risk that the improvement of the light emitting efficiency by plasmon resonance is prevented. In this circumstance, the inventors of the present invention have conceived of a structure that can adjust the energy level of the metal thin-film while the light emitting efficiency by plasmon resonance is sufficiently improved. Further, an electroluminescence device that can achieve high light emitting efficiency without reducing the durability of the device has been obtained.

### <El Device According to Third Embodiment>

FIG. 4 is a schematic diagram illustrating the structure of an electroluminescence device 3 according to the third embodiment. As illustrated in FIG. 4, the EL device 3 of the present embodiment includes an anode 51, a positive hole transport layer 53, a light emitting layer 54, an electron transport layer 55, and a cathode 56 deposited one on another on a transparent substrate 50, such as glass. Here, a multiplicity of core-shell-type microparticles 60, as a metal member, are dispersed in the positive hole transport layer 53. The core-shell-type microparticle 60 includes a metal microparticle core 61 and an insulation shell 62, which covers the metal microparticle core 61. The core-shell-type microparticles 60 induce plasmon resonance by the emitted light. Here, the insulation shell 62 is made of a transparent material, which transmits the emitted light. Here, the term “transparent” refers to having a transmittance that is greater than or equal to 70% with respect to the emitted light.

The EL device 3 of the present embodiment is also structured in such a manner that a cavity is formed between the electrodes 51 and 56, and a standing wave is generated in the device. In the EL device 3, the loop of the standing wave coincides with the light emitting layer 54. Each of the layers 53 to 55 is designed to have a refractive index and a thickness that satisfy the above mentioned resonance conditions. Further, the core-shell-type microparticles 60 are arranged in a region in which plasmon resonance by the light emitted from the light emitting layer 54 occurs. Accordingly, in a manner similar to the EL devices of the first and second embodiments, it is possible to achieve the combined effect of the microcavity effect and the plasmon enhancement effect. Further, it is sufficient if at least the metal microparticle core 61, included in the core-shell-type microparticle 60, is present in the vicinity of the light emitting region, in which plasmon resonance by the emitted light occurs.

When a metal member is inserted in the deposited layers as described above, the metal member may prevent the movement of charges. Therefore, in the present embodiment, the core-shell-type microparticles 60 are used as the metal member so that the movement of charges is not prevented. In the core-shell-type microparticle 60, for example, a silver microparticle is used as the metal microparticle core 61, and a dielectric, such as SiO₂, is used as the insulation shell 62. The silver microparticle 61, which contributes to plasmon resonance, is covered by the insulation shell 62. Therefore, even when an electric field is applied between the electrodes, charges (electrons or positive holes) are not trapped (disturbed) by Ag, which is a conductor. Consequently, normal movement of the charges is possible.

As described above, in the EL device 3 of the present embodiment, the core-shell-type microparticles 60 are used as the metal member. Therefore, it is possible to prevent the adverse effect on the movement of charges caused by the metal member during application of an electric field. Hence, it is possible to effectively improve the light emission efficiency and the durability by the microcavity effect and the plasmon enhancement effect.

An example of a method for producing the EL device 3 of the present embodiment will be described briefly.

The anode 51 made of Cu is formed on the transparent substrate 50 by vapor deposition. As the core-shell-type microparticle 60, a microparticle 61 of Ag that has a particle diameter of 50 nm is coated with SiO₂ 62 with the thickness of 10 nm. Next, the core-shell-type microparticles 60 are dispersed in dichloromethane, in which a triphenyl diamine derivative (TPD), as a positive hole transport material, is dissolved. Further, the solution is applied to the anode 51 by spin coating. Accordingly, the positive transport layer 53, in which the core-shell-type microparticles 60 are dispersed, is formed. Next, a phenanthroline derivative (BCP), as a light emitting material, and Alq3 (tris-(8-hydroxyquinoline) aluminum), as an electron transport material, are sequentially deposited by vapor deposition to form the light emitting layer 54 and the electron transport layer 55, respectively. Finally, the cathode 56 made of Ag is formed.

In the aforementioned example, the core-shell-type microparticles are dispersed in the positive hole transport layer 53. Alternatively, the core-shell-type microparticles 60 may be arranged or dispersed in any layer between the electrodes as long as plasmon resonance by the emitted light occurs in the region in which the core-shell-type microparticles 60 are arranged. When the core-shell-type microparticles 60 are present in the light emitting region, it is possible to effectively induce plasmon resonance, and that is desirable.

In FIG. 4, the multiplicity of core-shell-type microparticles 60 are present. However, even if only one core-shell-type microparticle 60 is present, it is possible to enhance the light emission effect by the plasmon resonance.

The particle diameter of the metal microparticle core of the core-shell-type microparticle is not particularly limited as long as localized plasmons are induced. It is desirable that the particle diameter of the metal microparticle core is less than or equal to the wavelength of the emitted light. Optionally, the particle diameter may be greater than or equal to 10 nm and less than or equal to 1 um (micro meter).

It is desirable that the thickness of the insulation shell 62 does not prevent the induction of localized plasmons at the metal microparticle cores 61 by the emitted light. It is desirable that a distance between the light emitting layer 54 and the surface of the metal microparticle core is less than or equal to 30 nm to effectively induce localized plasmons by the light emitted from the light emitting layer 54. Therefore, it is desirable that the position at which the core-shell-type microparticle 60 is arranged, the structure or arrangement of the layer, and the thickness of the insulation shell 62 are designed so that effective plasmon resonance is induced. Here, when only one metal microparticle 61 is included in the insulation shell 62, the thickness of the insulation shell 62 is an average distance between the surface of the insulation shell 62 and the surface of the metal microparticle core 61. When a plurality of metal microparticle cores 61 are included in the insulation shell 62, the thickness of the insulation shell 62 is an average value of a shortest distance between the surface of the insulation shell 62 and each of the metal microparticle cores 61.

The material of the metal microparticle core 61 should induce plasmon resonance by the emitted light. The material of the metal microparticle core 61 is not limited to Ag (silver). In a manner similar to the metal thin-film of the first embodiment, Au (gold), Cu (copper), Al (aluminum), Pt (platinum) or an alloy containing one of these metals as a main component (greater than or equal to 80 weight percent (wt %)) may be used.

Meanwhile, as the material of the insulation shell 62, an insulator, such as SiO₂, Al₂O₃, MgO, ZrO₂, PbO, B₂O₃, CaO and BaO, may be used.

In the above embodiments, each of the cathode, the electron injection layer, the electron transport layer, the light emitting layer, the positive hole transport layer, the positive hole injection layer, the anode, and the like may be made of materials selected from various well-known materials, each having an appropriate function. Further, a positive hole block layer, an electron block layer, a protective layer or the like may be provided.

Further, in each of the embodiments, the plurality of layers including the light emitting layer are organic compound layers. Alternatively, the EL device of the present invention may be an inorganic EL device, in which the plurality of layers including the light emitting layer are inorganic compound layers. Further, the EL device of the present invention may be appropriately applied to a light emitting diode including a plurality of semiconductor layers and a semiconductor laser.

Further, the EL device of the present invention may be appropriately applied to a display device or element, a display (display screen), a back light, an electronic photograph, a light source for lighting, a light source for recording, a light source for exposure, a light source for readout, a sign or mark, a signboard, an interior decoration or object, optical communication, and the like.

1.-7. (canceled)

8. An electroluminescence device comprising:
electrodes;
a plurality of layers that are deposited one on another between the electrodes; and
a light emitting region between the plurality of layers, the light emitting region emitting light by application of an electric field between the electrodes, wherein the thickness and the refractive index of each of the plurality of layers satisfy a resonance condition in the electroluminescence device that makes a region in which the intensity of the electric field of a standing wave by the light emitted from the light emitting region is the highest substantially coincide with the light emitting region, and wherein a metal member that induces plasmon resonance on the surface thereof by the emitted light is arranged in the vicinity of the light emitting region.

9. An electroluminescence device, as defined in claim 8, wherein the plurality of layers include at least an electron transport layer, a light emitting layer, and a positive-hole transport layer, and each of which is formed of an organic layer.

10. An electroluminescence device, as defined in claim 8, wherein a distance between the metal member and the light emitting region is less than or equal to 30 nm.

11. An electroluminescence device, as defined in claim 8, wherein the metal member is a metal thin-film arranged between the plurality of layers.

12. An electroluminescence device, as defined in claim 11, wherein the metal thin-film is an island-pattern thin-film, in which a multiplicity of metal microparticles having particle diameters greater than or equal to 5 nm are dispersed in layer form.

13. An electroluminescence device, as defined in claim 11, wherein surface modification is provided on at least one of the surfaces of the metal thin-film, the surface modification including an end group having polarity that makes the work function of the metal thin-film become close to the work function of at least a layer next to the metal thin-film.

14. An electroluminescence device, as defined in claim 8, wherein the metal member is a core-shell-type microparticle including a metal microparticle core and an insulation shell that covers the metal microparticle.
